(19) United States
(12) Patent Application Publication
(10) Pub. No.: US 2024/0402219 A1
(43) Pub. Date: Dec. 5, 2024

(54) PROBE CARD CLEANING ELEMENT WEAR DETECTION SYSTEM

(71) Applicant: Wayne Cooper Smith, Austin, TX (US)

(72) Inventor: Wayne Cooper Smith, Austin, TX (US)

(21) Appl. No.: 18/678,598

(22) Filed: May 30, 2024

Related U.S. Application Data
(60) Provisional application No. 63/470,922, filed on Jun. 4, 2023.

(51) Int. Cl. G01R 3/00; B08B 1/14; B08B 13/00

(52) U.S. Cl. CPC G01R 3/00; B08B 1/14; B08B 13/00

(57) ABSTRACT

A cleaning element and a method for utilizing the cleaning element within a semiconductor testing procedure may improve the efficiency of testing semiconductor wafers or chips by eliminating the need for personnel to manually and visually inspect cleaning elements when worn out. The cleaning element may be impregnated with conductive particles that lower the conductivity of the cleaning element to a degree which can be measured by the same probe card which tests the wafers. As the cleaning element is worn by usage in cleaning the probe tips, the conductivity will increase. The testing process using the probe card will periodically pause testing procedure, both to be cleaned by the cleaning element, and also to test the conductivity of the cleaning element.

### CROSS-REFERENCE TO RELATED APPLICATION(S)

The present application is related to and claims priority to U.S. Provisional Patent Application No. 63/470,922 filed Jun. 4, 2023, which is incorporated by reference herein in its entirety.

### BACKGROUND OF THE INVENTION

The following includes information that may be useful in understanding the present disclosure. It is not an admission that any of the information provided herein is prior art nor material to the presently described or claimed inventions, nor that any publication or document that is specifically or implicitly referenced is prior art.

### TECHNICAL FIELD

The present invention relates generally to the field of semiconductor manufacturing and more specifically relates to improvements for probe card cleaning systems.

### RELATED ART

A manufacturing process for semiconductor chips on wafers requires quality assurance testing for wafers leaving the production line. Testing procedures are well known in the art, and are completed by batch testing using an automated device known as a probe card. A probe card is mechanized to place a minimum of two conductive probes in contact with the chips on the wafer at predetermined locations on the wafer, The two conductive probes are connected to automated test equipment (ATE) which contains imbedded instruments, consisting at minimum of an ohmmeter to measures the total resistance of the circuit now completed by the wafer between the probes, known as the contact resistance (Cres).

This process is well known and effective. However, a limiting factor persists and has prevented full automation of the testing process. Due to contact wear and contamination of the probes by particles from the wafers, the probes require cleaning periodically between tested batches. If the probes are not cleaned, contaminants will influence the Cres values, leading to rejection of good chips on wafers or chips in a carrier.

Automated cleaning elements have been implemented to clean the probes. Liquid chemical applications and mechanical cleaning solutions have been attempted. These solutions may be effective at cleaning the probe tips. However, these cleaning elements interrupt the effective automation of the process when the cleaning elements themselves wear out. A manufacturer must assign labor to regularly inspect these cleaning elements when the wear out, and then replace them as required. Allocation of this labor is burdensome. Worse, often labor fails to recognize a worn cleaning element in time. This leads to dirty probe tips and rejection of good chips on wafers or chips in a carrier. There is seen a need for a superior solution which eliminates the wasted time and error caused by this manual inspection.

Various attempts have been made to solve problems found in the general problem of measuring wear of cleaning consumables. Among these are found in U.S. patents u and U.S. Pat. No. 5,814,158. However, these solutions cannot be applied directly to probe card systems, and wafer/chip testing technology has offered no solutions for eliminating the visual inspection of probe card cleaning elements. Accordingly, none of the above inventions and patents, taken either singly or in combination, is seen to describe the invention as claimed. Thus, a need exists for a reliable system for testing probe card cleaning elements, and to avoid the above-mentioned problems.

### BRIEF SUMMARY OF THE INVENTION

The present invention advantageously fills the aforementioned deficiencies by providing a novel probe card cleaning element wear detection system. The present invention is superior to other systems in that it effectively eliminates the need for personnel to manually and visually inspect cleaning elements for a probe card, both reducing labor and also preventing accidental failure of the cleaning system and improper testing of semiconductor chips.

A cleaning element and a method for utilizing the cleaning element within a semiconductor testing procedure may improve the efficiency of testing semiconductor wafers or chips in a carrier by eliminating the need for personnel to manually and visually inspect cleaning elements when worn out. The cleaning element may be impregnated with metallic particles that raise the conductivity of the cleaning element to a degree which can be measured by the same probe card which tests the wafers or chips in a carrier. As the cleaning element is worn by usage in cleaning the probe tips, the conductivity will decrease. The system will periodically pause testing procedure, both to be cleaned by the cleaning element, and also to test the conductivity of the cleaning element. When the contact resistance of the cleaning element is above a predetermined value, the system will notify personnel that the cleaning element must be replaced.

The features of the invention which are believed to be novel are particularly pointed out in the specification. The present invention now will be described more fully hereinafter with reference to the accompanying drawings, which are intended to be read in conjunction with both this summary, the detailed description and any preferred and/or particular embodiments specifically discussed or otherwise disclosed. This invention may, however, be embodied in many different forms and should not be construed as limited to the embodiments set forth herein; rather, these embodiments are provided by way of illustration only and so that this disclosure will be thorough, complete and will fully convey the full scope of the invention to those skilled in the art.

### BRIEF DESCRIPTION OF THE DRAWINGS

The figures which accompany the written portion of this specification illustrate embodiments and methods of use for the present invention, a probe card cleaning element wear detection system, constructed and operative according to the teachings of the present invention.

FIG. 1 is a chart illustrating a method of use of a probe card cleaning element wear detection system.

FIG. 2 is a perspective view a prior art probe card.

FIG. 3 is a perspective view of the probe card cleaning element wear detection system operating upon a wafer, according to an embodiment of the present invention.

FIG. 4 is a perspective view of the cleaning element construction of the probe card cleaning element wear detection system of FIG. 3 according to an embodiment of the present invention.

FIG. 5 is a diagram of the probe card cleaning element wear detection system of FIG. 3 being used to measure the contact resistance of the cleaning element according to an embodiment of the present invention.

The various embodiments of the present invention will hereinafter be described in conjunction with the appended drawings, wherein like designations denote like elements.

### DETAILED DESCRIPTION

The present invention is directed to a probe card cleaning element wear detection system. In one embodiment of the present invention, the probe card cleaning element wear detection system may include a cleaning element construction, a system using the cleaning element construction, and a method of operating the system.

The probe card cleaning element wear detection system may include a probe card system with an integrated cleaning element area for cleaning the probe card, and a testing system for evaluating usability of the probe card and the cleaning element. As integrated, the system may improve the automated maintenance of probe cards to prevent degradation of the operation of the system, and accidental rejection of usable chips in the semiconductor products manufacture. A cleaning element substrate may be composed of a polymer with interspersed conductive embedded particles in order to produce a wearable cleaning element that has a known conductive value per volume unit. Having a known conductive value per volume unit, the wearable cleaning element may be tested as part of an automated procedure by the same probing system which tests the wafers or chips in a carrier. An adhesive layer may affix the substrate to a work area; the cleaning element may be replaceable when it is worn beyond proper use. The substrate, making up the bulk of the mass and cleaning surface of the cleaning element, may be of a sponge-like consistency with a smooth or textured surface able to abrade against the probe card tips, thereby cleaning residue and oxidation, without significantly wearing into the probe card tips themselves.

All three types of cleaning element embodiments described herein (sponge, elastomeric and PET coated) have abrasive particles glued to the surface and/or imbedded into the cleaning element. The base materials used to create the sponge, elastomeric structure, or PET coated films are typically a type of nonconductive plastic materials with similar nonconductive abrasive particles. The abrasive particles used in the construction of these cleaning elements in prior art examples may be Silicon Carbide or Aluminum Oxide, which is more resistive, or have too low conduction to be used to accurate measurements.

By changing the base materials to a more conductive material and adding low resistance abrasive particles to the base material the cleaning element, the cleaning element can be made conductive or low resistance. The base materials can be made conductive by embedding metallic particles such as Aluminum (Al,) Gold (Au), Silver (Ag) or imbedded more conductive compounds such as Tungsten carbide particles (WC), Titanium Carbide (TiC), Silicon Carbide (SiC), Aluminum Oxide (AlO), similar conduction compounds, or a combination of these compounds.

It is most preferable that the metallic particles be embedded into the PET body of the cleaning element, and in the coating upon the PET body. This coating may be a carrier film placed upon a side of the PET body. This film may be composed of five to sixty percent metal by weight. The cleaning element may be mounted on a silicon wafer or other substrate, or on a sub chuck cleaning block.

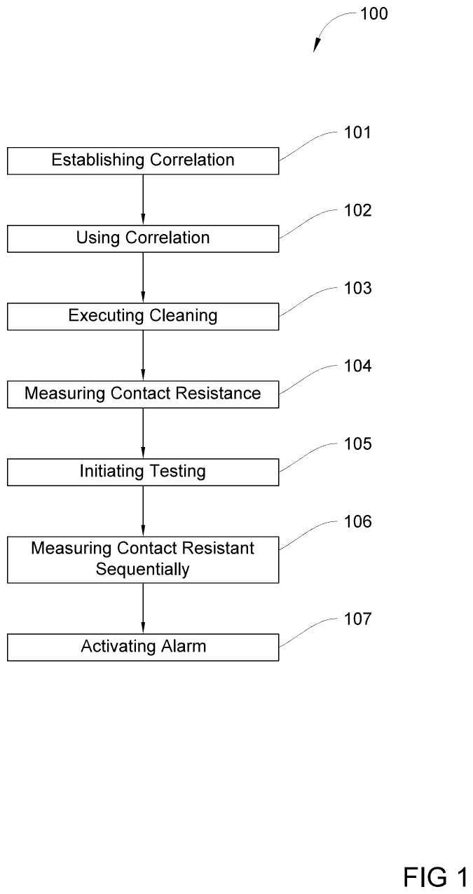

Referring now to FIG. 1, there is shown a method for a testing process 100. This testing process monitors the contact resistance change during the normal cleaning cycles. For example, when the wafer/chip testing is paused to clean the probe tips, the cleaning procedure may be preceded or succeeded by a test of the contact resistance of the cleaning element. The method of the testing process 100 for monitoring the contact resistance of the cleaning element may include the following steps:

Step one 101: Use existing testing and yield monitoring tools establish a correlation between increasing contact resistance and yield loss.

Step two 102: Using the correlation data from step one, establish a max allowable contact resistance that does not cause yield loss.

Step three 103: Execute the normal probe or pin cleaning on the testing system equipment using the a new conductive cleaning element.

Step four 104: During the normal cleaning cycle when the cleaning element and the probe or pin are in contact, measure the contact resistance. The contact resistance is the base line resistance of the cleaning element and a clean probe or pin.

Step five 105: Start the testing and probe or pin cleaning process as normal.

Step six 106: During each subsequent normal probe cleaning cycle, measure the contact resistance while the probe in contact with the cleaning element.

Step seven 107: When the contact resistance reaches the maximum allowable limit established in step 2, have the testing system alarm using the existing alarming methods.

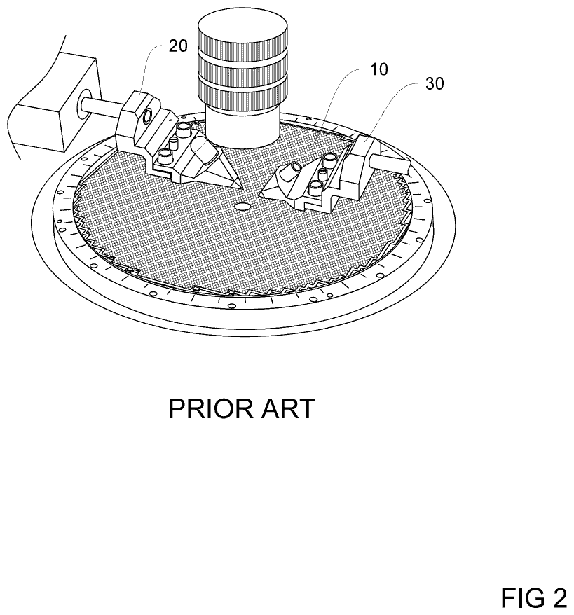

Referring now to FIG. 2, there is shown a prior art example of a silicone wafer 10 being tested by a traditional probing method. The probe card includes a first probe 20 and a second probe 30, which are connected to appropriate digital equipment able to measure a resistance between first probe 20 and second probe 30 when first probe 20 and second probe 30 are in contact with wafer 10.

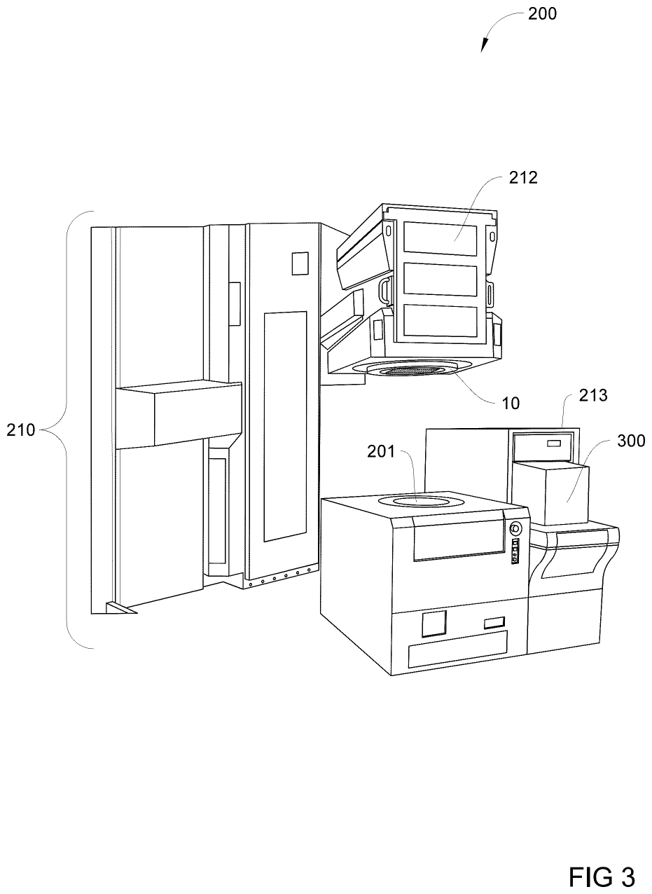

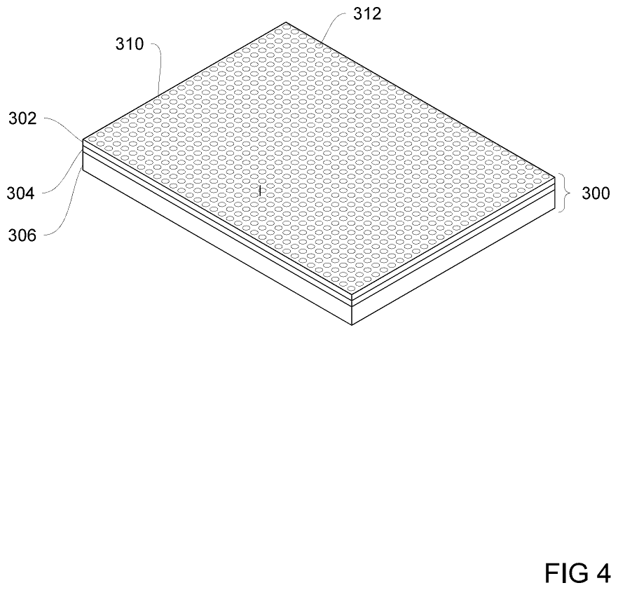

Referring now to FIG. 3, there is shown a diagram of a probe card being used to measure the contact resistance (Cres) of the cleaning element. As shown, wafer 10 is mounted to mounting base 201 as a secure platform for the probe card system to operate over. For the purpose of this specification, the term “wafer” should be understood to include bare wafers, or more often, manufactured chips with integrated circuits. Furthermore, it should be understood that the disclosed equipment is preferably arranged to test wafers and chips in chip carriers. Wafer 10 must be rigidly affixed to mounting base 201 such that it remains in a fixed and measurable position to be measured by the probe card system. The method disclosed herein may utilize an existing semiconductor wafer testing station, here represented by testing head 212, and may implement steps to use and existing tester in order to test the conductive cleaning element 300 (FIG. 4) on the cleaning wafer or sub chuck cleaning block. Cleaning element 300 may be mounted inside prober 213, preferably upon a chuck. Cleaning element 300 may be in the form of a wafer, block, or other structure. As shown, the ATE 210 uses existing capabilities to alarm service personnel, with preferably an audible and or visual alarm. Visual and audio alarms may be used to notify when cleaning element replacement is required. The ATE may be capable of moving the probe card 10 upon test head 310 as needed according to predetermined programming. By using the existing capability of the ATE and this conductive cleaning element 300 (FIG. 4) and measuring the change in electrical properties of the cleaning element 300 (FIG. 4), the effectiveness of the cleaning process can be monitored by using the existing testing hardware and software to measure the contact resistance of the cleaning element 300 (FIG. 4). By establishing a maximum change in contract resistance and monitoring the increase in contact resistance, the testing hardware can alarm, thereby signifying that the cleaning element needs to be replaced. Accordingly, there is no need for personnel to manually and visually inspect cleaning elements, as the system will notify personnel when the cleaning element needs to be replaced for continued function of the probing system within acceptable performance boundaries.

There is shown in FIG. 4 a representation of the cleaning element 300 according to an embodiment of the present invention. Shown is a substrate 302 and conductive embedded particles (represented by circular icons) 312 within or upon substrate 302. Substrate 302 may be a conductive polymer, constructed by a polymer material 310 interspersed with conductive particles 312. As before, this matrix is preferably constructed only in a thin film applied over mounting block or wafer 306. Also shown is an adhesive layer 304 to affix the cleaning element 300 to mounting block or wafer 306. The substrate 302, making up the cleaning surface of the cleaning element, may be of a sponge-like consistency with a smooth or textured surface. An ideal material for the polymer component 310 of the cleaning element 300 is seen to be PET (polyethylene terephthalate). However, other polymers may be implemented. Substrate 302 may be rigidly affixed to the work area by mounting block or wafer 306.

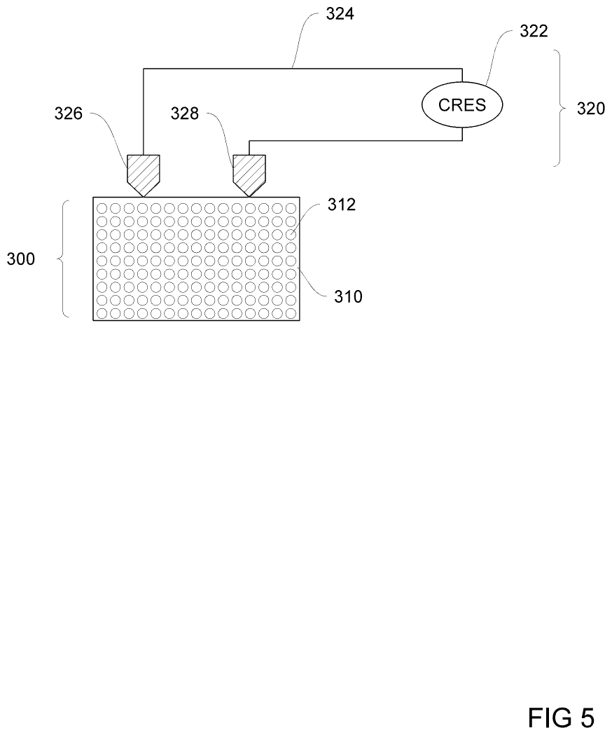

There is shown in FIG. 5 a diagram of the operation of the probe card system interacting with the cleaning element 300 according to an embodiment of the present invention during an in-use condition. As shown, first-probe 326 and second-probe 328 are electrically connected to testing system 320 (probe card 324). Testing system 320 may include a measurer 322 (that is, a resistive sensor such as an ohm meter) and may also include a commuting system for processing, storing, and communicating resistance data. In use, first-probe 326 and second-probe 328 are passed over cleaning element 300 in order to clean first-probe 326 and second-probe 328 as they contact cleaning element 300. The testing step may be performed simultaneously, prior to, or subsequently to the cleaning step in various embodiments. Testing occurs when first-probe 326 and second-probe 328 are both simultaneously in contact with cleaning element 300. Because cleaning element 300 is composed of polymer material 310 and conductive particle 312, cleaning element 300 has a conductive value range known to testing system 320. When first-probe 326 and second-probe 328 are in contact with cleaning element 300, measurer 322 measures and records a resistance value of the circuit formed by cleaning element 300 connecting first-probe 326 and second-probe 328. If the recorded value is within the proper conductive value range, then testing system 320 determines that the cleaning element remains in usable condition, and the process proceeds. However, if the recorded value is outside of the proper conductive value range, then the testing system 320 determines that the cleaning element is no longer suitable for continued use, and triggers alarm in the ATE 210 (FIG. 3). Optionally, when the alarm in the ATE 210 (FIG. 3) is triggered, the entire system may pause until service personnel reset the system. In this way, cleaning of the probes is automated, and the system pauses when the cleaning elements are out of specification and require replacement. As such, failure of the system due to compromised test probes and cleaning elements alike.

The exact specifications, materials used, and method of use of the probe card cleaning element wear detection system may vary upon manufacturing.

The foregoing descriptions of specific embodiments of the present invention have been presented for purposes of illustration and description. They are not intended to be exhaustive or to limit the present invention to the precise forms disclosed, and obviously many modifications and variations are possible in light of the above teaching. The exemplary embodiment(s) were chosen and described in order to best explain the principles of the present invention and its practical application, to thereby enable others skilled in the art to best utilize the present invention and various embodiments with various modifications as are suited to the particular use contemplated.

1. A method for determining the usability of a cleaning element for cleaning probe cards, the method comprising the steps of
establishing a correlation between increasing contact resistance and yield loss;
using the correlation, establish a max allowable contact resistance that does not cause yield loss over a predetermined amount;
executing the normal probe or pin cleaning on the prober equipment using the new conductive cleaning element;
during the normal cleaning cycle when the cleaning element and the probe or pin are in contact, measuring the contact resistance, whereby the contact resistance is the base line resistance of the cleaning element and a clean probe or pin;
initiating the testing and probe or pin cleaning process as normal;
during each subsequent normal probe cleaning cycle, measuring the contact resistance while the probe in contact with the cleaning element; and
when the contact resistance reaches the maximum allowable limit established in step 2, having the tester alarm using the existing alarming methods.

2. A cleaning element for polishing probe tips, the cleaning element comprising:
a cleaning block;
a conductive film applied to a lateral side of the cleaning block,
an adhesive applied to the back side of the PET to adhere the cleaning element to the cleaning block and able to mount the cleaning block to a mounting structure.

3. The cleaning element of claim 2, wherein the conductive film contains between five and sixty percent of an embedded metallic particle.

4. The cleaning element of claim 3, wherein the embedded metallic particle comprises one or more selected from the group comprising aluminum, gold, silver, tungsten carbide particles, titanium carbide, silicon carbide, silicon, platinum, bronze, zinc, iron, brass, nickel, graphite, lead, and aluminum oxide.

5. The cleaning element of claim 2, wherein the cleaning block comprises polymer.

6. The cleaning element of claim 2, wherein the cleaning block comprises polyethelene terephthalate.

7. A probe card cleaning element wear detection system comprising
the cleaning element of claim 2;
a probe card able to automatically contract predetermined regions of a wafer and alternatively predetermined regions of the cleaning element;
an integrated testing system able to determine whether a first contact resistance measured by the probe card on the wafer is within a first predetermined range, and able to determine whether a second contact resistance measured by the probe card on the cleaning element is within a second predetermined range; and
an alarm;
wherein the integrated testing system includes a procedure for cleaning the probe card with the cleaning block;
wherein the integrated testing system determines whether the first contact resistance of the cleaning element is within the first predetermined range when the probe card is in electrical contact with the cleaning element;
wherein the integrated testing system determines whether the second contact resistance is within the second predetermined range when the probe card is in electrical contact with the cleaning element; and
wherein the integrated testing system activates the alarm if the second contact resistance is not within the second predetermined range.

8. The probe card cleaning element wear detection system of claim 7, wherein
the integrated testing system halts operation of the probe card if the second contact resistance is not within the second predetermined range.
